(19) United States
(12) Patent Application Publication
(10) Pub. No.: US 2026/0101560 A1
(43) Pub. Date: Apr. 9, 2026

(54) SEMICONDUCTOR DEVICE COMPRISING GALLIUM NITRIDE LAYER AND METHOD FOR MANUFACTURING SAME

(71) Applicant: DB HiTek Co., Ltd., Seoul (KR)

(72) Inventors: Min Su CHO, Eumseong-gun (KR); Jonh Hyun LEE, Eumseong-gun (KR); Dae II KIM, Eumseong-gun (KR); Ji Houn JUNG, Eumseong-gun (KR); Hee Sub LEE, Eumseong-gun (KR); Ung Bi SON, Eumseong-gun (KR); Jun Hyeok LEE, Eumseong-gun (KR); Chang Wan AHN, Eumseong-gun (KR)

(21) Appl. No.: 19/266,561

(22) Filed: Jul. 11, 2025

(30) Foreign Application Priority Data
Oct. 8, 2024 (KR) 10-2024-0136372

(51) Int. Cl. H10D 64/00; H10D 30/01; H10D 30/47; H10D 62/85; H10D 64/01

(52) U.S. Cl. CPC H10D 64/111; H10D 30/015; H10D 30/475; H10D 62/8503; H10D 64/01

(57) ABSTRACT

A semiconductor device is provided. The semiconductor device comprising: a substrate; a semiconductor material layer on the substrate; a dielectric layer on the semiconductor material layer; and a first recess, a second recess, and a third recess arranged in the dielectric layer and spaced apart from one another; a first field plate portion filling the first recess; a second field plate portion filling the second recess; and a third field plate portion filling the third recess, wherein a first width of a first bottom surface of the first recess, a second width of a second bottom surface of the second recess, and a third width of a third bottom surface of the third recess are different from one another.

### PRIORITY CLAIM

This application claims priority under 35 U.S.C § 119 to Korean Patent Application No. 10-2024-0136372 filed on Oct. 8, 2024, in the Korean Intellectual Property Office, the entire contents of which are hereby incorporated by reference

### TECHNICAL FIELD

The present disclosure relates to a semiconductor device comprising a gallium nitride layer and a method for manufacturing the same, and more particularly, to a power semiconductor device and a method for manufacturing the same.

### BACKGROUND

The content described in this section simply provides background information for the present embodiment and does not constitute the prior art.

A semiconductor device comprising a gallium nitride (GaN) layer is widely used in the field of power semiconductors.

Meanwhile, a field plate in a power semiconductor device serves to disperse an electric field generated by a high drain bias applied to a gate and a drain drift region, thereby improving a breakdown voltage of the semiconductor device. However, when an electric field is concentrated on an edge of the field plate at a high voltage of about 700 V or more, a crack (e.g., breakdown) may occur because an insulating layer (e.g., oxide) at the edge of the field plate cannot withstand the field.

Accordingly, a structure in which a plurality of field plates are stacked has been used, such that the electric field can be sequentially dispersed. However, a structure in which a plurality of field plates are stacked has a disadvantage in that a plurality of masks must be used.

### SUMMARY

An object of the present disclosure is to provide a semiconductor device comprising a gallium nitride layer and a method for manufacturing the same, the semiconductor device including a field plate structure capable of dispersing an electric field.

The objects of the present disclosure are not limited to the above-mentioned objects, and other objects and advantages of the present disclosure that are not mentioned will be understood by the following description and will be more clearly understood by embodiments of the present disclosure. In addition, it will be easy to see that the objects and advantages of the present disclosure may be realized by the means and combinations thereof disclosed in the claims.

According to some aspects of the disclosure, a semiconductor device comprising: a substrate; a semiconductor material layer on the substrate; a dielectric layer on the semiconductor material layer; and a first recess, a second recess, and a third recess arranged in the dielectric layer and spaced apart from one another; a first field plate portion filling the first recess; a second field plate portion filling the second recess; and a third field plate portion filling the third recess, wherein a first width of a first bottom surface of the first recess, a second width of a second bottom surface of the second recess, and a third width of a third bottom surface of the third recess are different from one another.

According to some aspects, wherein the second recess is arranged between the first recess and the third recess, and the second field plate portion is arranged between the first field plate portion and the third field plate portion.

According to some aspects, wherein the first width is greater than the second width, and the second width is greater than the third width.

According to some aspects, wherein the dielectric layer includes: a first portion between the first recess and the second recess, and a second portion between the second recess and the third recess.

According to some aspects, wherein the second field plate portion overlaps, along a first direction parallel to an upper surface of the substrate, a first portion of the first plate portion and the first portion of the dielectric layer, and the third field plate portion overlaps, along the first direction, a second portion of the first plate portion, a portion of the first portion of the dielectric layer, a first portion of the second field plate portion, and the second portion of the dielectric layer. According to some aspects, a first protruding portion on the first field plate portion; a second protruding portion on the second field plate portion; a third protruding portion on the third field plate portion; a first connection portion that connects the first protruding portion and the second protruding portion, and is arranged on the first portion of the dielectric layer; a second connection portion that connects the second protruding portion and the third protruding portion, and is arranged on the second portion of the dielectric layer; and a fourth protruding portion that is connected to the third protruding portion and is arranged on an upper surface of the dielectric layer.

According to some aspects, wherein the first field plate portion, the second field plate portion, the third field plate portion, the first protruding portion, the second protruding portion, the third protruding portion, the first connection portion, and the second connection portion include the same material.

According to some aspects, wherein a first height from an upper surface of the substrate to the first bottom surface, a second height to the second bottom surface, and a third height to the third bottom surface are different from one another.

According to some aspects, wherein the third height is greater than the second height, and the second height is greater than the first height.

According to some aspects, a gate electrode that is spaced apart from the first field plate portion, the second field plate portion, and the third field plate portion, is arranged in the dielectric layer, and is arranged on the substrate.

According to some aspects of the disclosure, a semiconductor device comprising: a substrate; a semiconductor material layer on the substrate; a dielectric layer on the semiconductor material layer; a first field plate portion and a second field plate portion arranged in the dielectric layer and spaced apart from each other; a first portion of the dielectric layer arranged between the first field plate portion and the second field plate portion; a first protruding portion on the first field plate portion; a second protruding portion on the second field plate portion; and a first connection portion arranged on the first portion of the dielectric layer and connecting the first protruding portion and the second protruding portion.

According to some aspects, a first recess and a second recess arranged in the dielectric layer and spaced apart from each other, wherein the first field plate portion fills the first recess, and the second field plate portion fills the second recess.

According to some aspects, wherein a first width of a first bottom surface of the first recess and a second width of a second bottom surface of the second recess are different from each other.

According to some aspects, wherein the first width is greater than the second width.

According to some aspects, wherein a first height from an upper surface of the substrate to the first bottom surface and a second height to the second bottom surface are different from each other.

According to some aspects, wherein the second height is greater than the first height.

According to some aspects, wherein the second field plate portion overlaps, along a first direction parallel to an upper surface of the substrate, a first portion of the first plate portion and the first portion of the dielectric layer.

According to some aspects, wherein the first field plate portion, the second field plate portion, the first protruding portion, the second protruding portion, and the first connection portion include the same material.

According to some aspects, a gate electrode that is spaced apart from the first field plate portion and the second field plate portion, is arranged in the dielectric layer, and is arranged on the substrate.

According to some aspects of the disclosure, a method for manufacturing a semiconductor device, comprising: providing a substrate on which a dielectric layer is formed and in which a gate electrode is formed in the dielectric layer; forming a mask layer on the substrate, the mask layer including a first slit having a first width and a second slit having a second width, wherein the first width and the second width are different from each other; removing a portion of each of the portions of the dielectric layer exposed by the first slit and the second slit, respectively, to form a first recess by the first slit and a second recess by the second slit in the dielectric layer; removing the mask layer; and forming a field plate that fills the first recess and the second recess and covers a portion of an upper surface of the dielectric layer.

According to some aspects, wherein a first height from an upper surface of the substrate to a first bottom surface of the first recess is different from a second height to a second bottom surface of the second recess.

According to some aspects, wherein the field plate is formed such that a first field plate portion that fills the first recess and a second field plate portion that fills the second recess are connected to each other.

According to the field plate structure of the semiconductor device of the present disclosure, the electric field may be dispersed to prevent breakdown at an edge of the field plate, thereby improving the reliability of the device.

In addition, according to the field plate structure in the method for manufacturing the semiconductor device of the present disclosure, the field plate may be formed through a single process using one mask, thereby securing economic efficiency.

In addition to the above, the specific effects of the present disclosure will be described together with the detailed description for implementing the present disclosure.

### BRIEF DESCRIPTION OF THE DRAWINGS

FIGS. 1A, 1B, 1C, and 1D are cross-sectional views of a semiconductor device according to an embodiment of the present disclosure.

FIG. 2 is a cross-sectional view in which a field plate is removed from FIGS. 1A, 1B, 1C, and 1D.

FIG. 3 is a flowchart for explaining a method for manufacturing a semiconductor device according to an embodiment of the present disclosure.

FIG. 4 is a cross-sectional view for explaining step S100 of FIG. 3.

FIG. 5 is a cross-sectional view for explaining step S200 of FIG. 3.

FIG. 6 is a cross-sectional view for describing step S300 of FIG. 3.

### DETAILED DESCRIPTION OF THE DRAWINGS

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

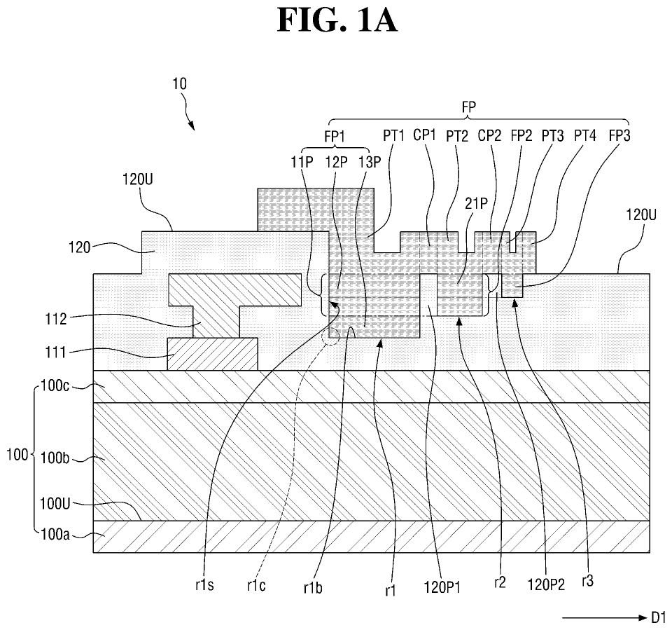

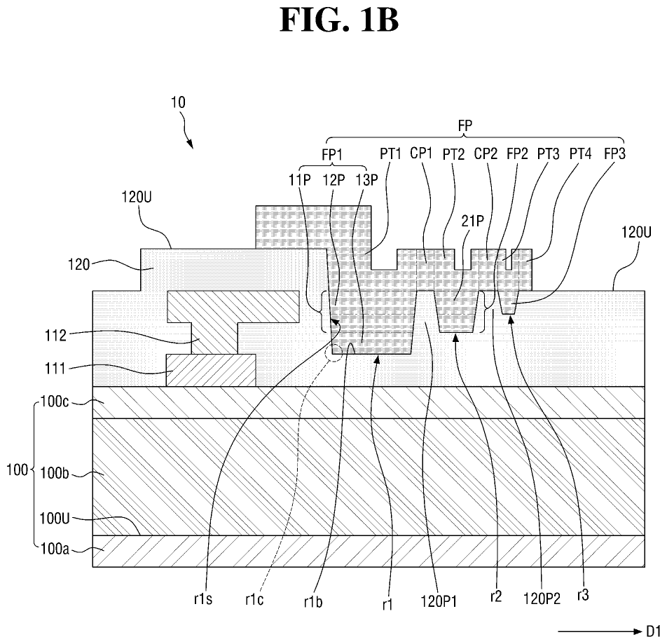

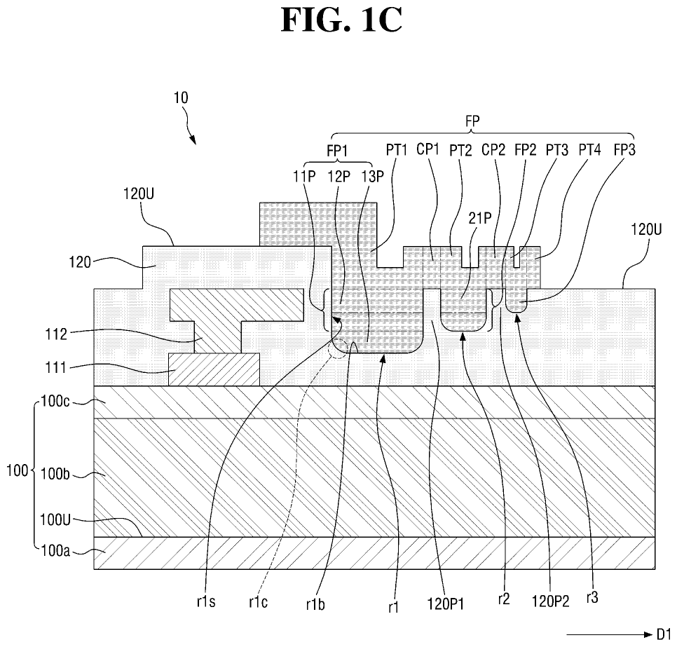

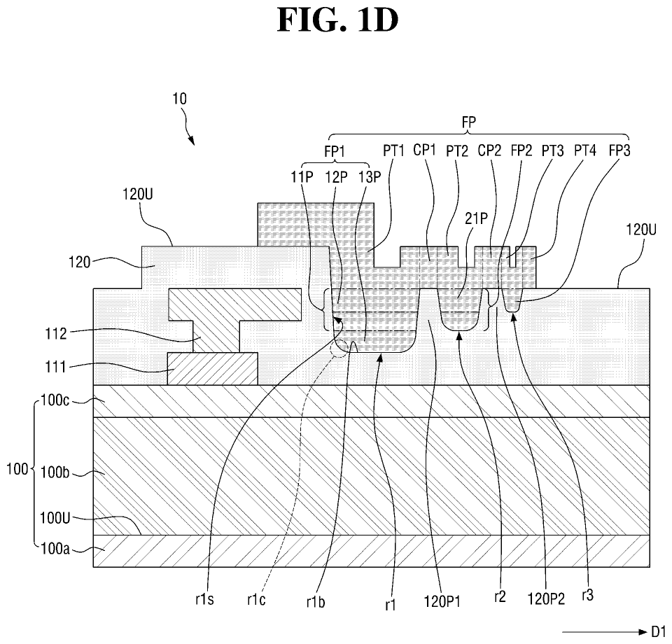

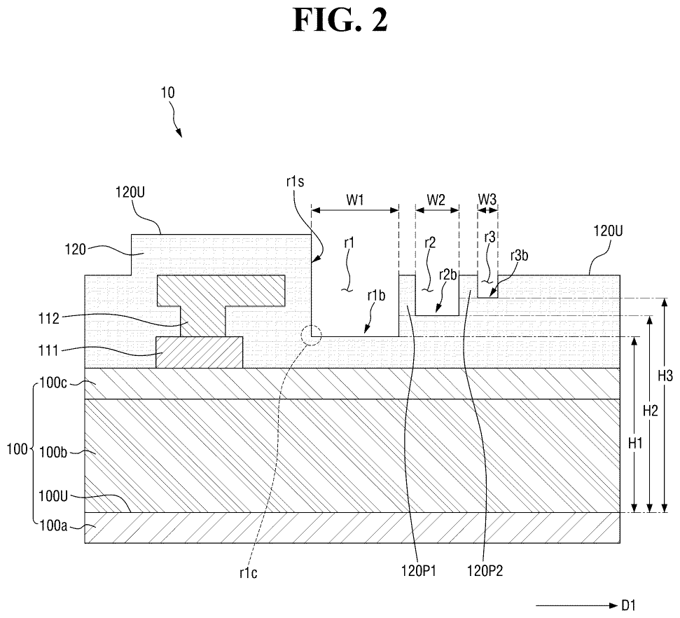

Hereinafter, a semiconductor device comprising a gallium nitride layer according to an embodiment of the present disclosure will be described with reference to FIGS. 1A, 1B, 1C, 1D, and 2.

FIGS. 1A, 1B, 1C, and 1D are cross-sectional views of a semiconductor device according to an embodiment of the present disclosure. FIG. 2 is a cross-sectional view in which a field plate is removed from FIGS. 1A, 1B, 1C, and 1D.

Referring to FIGS. 1A and 2, a semiconductor device 10 according to an embodiment of the present disclosure may include a base layer 100, a doped semiconductor layer 111, a gate electrode 112, a dielectric layer 120, and a field plate FP.

The base layer 100 may include a substrate 100a, a semiconductor layer 100b, and a semiconductor compound layer 100c.

The substrate 100a may be, for example, bulk silicon or silicon-on-insulator (SOI). Alternatively, the substrate 100a may be a silicon substrate.

The semiconductor layer 100b may be arranged on the substrate 100a. The semiconductor layer 100b may include, for example, gallium nitride (GaN).

The semiconductor compound layer 100c may be arranged on the semiconductor layer 100b. The semiconductor compound layer 100c may include other compounds comprising gallium nitride. For example, the semiconductor compound layer 100c may include any one of AlGaN, AlN, or InGaN.

The doped semiconductor layer 111 may be arranged on the base layer 100. The doped semiconductor layer 111 may be arranged, for example, on a portion of an upper surface of the base layer 100. The doped semiconductor layer 111 may be, for example, a doped nitride-based semiconductor layer. The doped semiconductor layer 111 may include, for example, a p-type group III-V semiconductor material. For example, the doped semiconductor layer 111 may include p-type GaN, p-type AlGaN, p-type InN, p-type AlInN, p-type InGaN, p-type AlInGaN, or a combination thereof. The p-type material may be, for example, a p-type impurity such as Be, Zn, Cd, or Mg.

The gate electrode 112 may be arranged on the doped semiconductor layer 111. In FIG. 1A, the gate electrode is illustrated as having a certain shape, but it is not limited thereto and may of course have other shapes. The gate electrode 112 may be formed as a single layer. Alternatively, the gate electrode 112 may be formed of a plurality of layers made of the same or different materials. The gate electrode 112 may include a metal or a metal compound. The gate electrode 112 may include, for example, at least one of TiN, WN, TaN, Ru, TiC, TaC, Ti, Ag, Al, TiAl, TiAlN, TiAlC, TaCN, TaSiN, Mn, Zr, W, or Al.

The dielectric layer 120 may be arranged on the base layer 100. The doped semiconductor layer 111 and the gate electrode 112 may be arranged within the dielectric layer 120.

The dielectric layer 120 may include, for example, at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate, but is not limited thereto.

The dielectric layer 120 may include a first recess r1, a second recess r2, and a third recess r3. The first recess r1, the second recess r2, and the third recess r3 may be disposed in the dielectric layer 120. The second recess r2 may be arranged between the first recess r1 and the third recess r3.

The first recess r1, the second recess r2, and the third recess r3 may be spaced apart from one another. For example, the first recess r1 and the second recess r2 may be spaced apart from each other, and a first portion 120P1 of the dielectric layer 120 may be arranged between the first recess r1 and the second recess r2. For example, the second recess r2 and the third recess r3 may be spaced apart from each other, and a second portion 120P2 of the dielectric layer 120 may be arranged between the second recess r2 and the third recess r3.

Sidewalls and bottom surfaces of the first recess r1, the second recess r2, and the third recess r3 may be defined by the dielectric layer 120.

In some embodiments, a sidewall r1s of the first recess r1 may not have an inclination. The sidewall r1s of the first recess r1 may be perpendicular to the upper surface 100U of the substrate 100a. A corner r1c where the sidewall r1s of the first recess r1 meets the first bottom surface r1b may have an angle close to 90 degrees. The details regarding the sidewalls and bottom surfaces of the recess may also be equally applied to the second recess r2 and the third recess r3. Accordingly, a first field plate portion FP1, a second field plate portion FP2, and a third field plate portion FP3 of a field plate FP to be described below may each have a shape corresponding to the shape of the respective recesses r1, r2, and r3 in which they are arranged.

Referring to FIG. 1B, in some embodiments, a sidewall r1s of the first recess r1 may have a slope. The details regarding the sidewalls may also be equally applied to the second recess r2 and the third recess r3. Accordingly, a first field plate portion FP1, a second field plate portion FP2, and a third field plate portion FP3 of a field plate FP to be described below may each have a shape corresponding to the shape of the respective recesses r1, r2, and r3 in which they are arranged.

Referring to FIG. 1C, in some embodiments, a corner r1c where the sidewall rs of the first recess r1 and a first bottom surface r1b meet may have a rounded shape. The details regarding the bottom surfaces may also be equally applied to the second recess r2 and the third recess r3. Accordingly, a first field plate portion FP1, a second field plate portion FP2, and a third field plate portion FP3 of a field plate FP to be described below may each have a shape corresponding to the shape of the respective recesses r1, r2, and r3 in which they are arranged.

Referring to FIG. 1D, in some embodiments, the sidewall rls of the first recess rl may have a slope. A corner rlc where the sidewall rls and a first bottom surface r1b of the first recess r1 meet may have a rounded shape. The details regarding the sidewalls and bottom surfaces may also be equally applied to the second recess r2 and the third recess r3. Accordingly, a first field plate portion FP1, a second field plate portion FP2, and a third field plate portion FP3 of a field plate FP to be described below may each have a shape corresponding to the shape of the respective recesses r1, r2, and r3 in which they are arranged.

Referring again to FIGS. 1A and 2, a first bottom surface rib of the first recess r1 may have a first width W1, a second bottom surface r2b of the second recess r2 may have a second width W2, and a third bottom surface r3b of the third recess r3 may have a third width W3. The first width W1, the second width W2, and the third width W3 may be different from each other. For example, the first width W1 may be greater than the second width W2, and the second width W2 may be greater than the third width W3.

Even in embodiments in which the sidewalls of the recesses have slopes (e.g., FIGS. 1B and 1D), the first width W1 may be greater than the second width W2, and the second width W2 may be greater than the third width W3.

A first height H1 from an upper surface 100U of the substrate 100a to the first bottom surface r1b, a second height H2 from the upper surface 100U of the substrate 100a to the second bottom surface r2b, and a third height H3 from the upper surface 100U of the substrate 100a to the third bottom surface r3b may be different from one another. For example, the third height H3 may be greater than the second height H2, and the second height H2 may be greater than the first height H1.

The gate electrode 112 may be spaced apart from the first recess r1, the second recess r2, and the third recess r3, and may be arranged within the dielectric layer 120. The first recess r1 may be arranged between the gate electrode 112 and the second recess r2. In a direction from the gate electrode 112 toward the third recess r3, the widths W1, W2, and W3 of the bottom surfaces r1b, r2b, and r3b of the respective first recess r1, second recess r2, and third recess r3 may gradually decrease, and the heights H1, H2, and H3 from the upper surface 100U of the substrate 100a to the bottom surfaces r1b, r2b, and r3b of the respective first recess r1, second recess r2, and third recess r3 may gradually increase.

Although the dielectric layer 120 is illustrated in the drawings as including three recesses, it is not limited thereto. For example, the dielectric layer 120 may include fewer than three recesses or more than three recesses. When fewer than three recesses or more than three recesses are included in the dielectric layer, the recesses may have bottom surface widths that gradually decrease in a direction away from the gate electrode 112, and the heights from the upper surface 100U of the substrate 100a to the bottom surfaces of the recesses may gradually increase.

The field plate FP may fill each of the first recess r1, the second recess r2, and the third recess r3, and may be arranged to cover a portion of an upper surface 120U of the dielectric layer 120.

The field plate FP may include a first field plate portion FP1, a second field plate portion FP2, a third field plate portion FP3, a first protruding portion PT1, a second protruding portion PT2, a third protruding portion PT3, a fourth protruding portion PT4, a first connection portion CP1, and a second connection portion CP2.

The first field plate portion FP1 may fill the first recess r1. The first protruding portion PT1 may be arranged on the first field plate portion FP1. A portion of the first protruding portion PT1 may extend on the upper surface 120U of the dielectric layer 120 along the upper surface 120U of the dielectric layer 120.

The second field plate portion FP2 may fill the second recess r2. The second protruding portion PT2 may be arranged on the second field plate portion FP2.

The third field plate portion FP3 may fill the third recess r3. The third protruding portion PT3 may be arranged on the third field plate portion FP3. The second field plate portion FP2 may be arranged between the first field plate portion FP1 and the third field plate portion FP3.

The fourth protruding portion PT4 may be arranged on an upper surface 120U of the dielectric layer 120. The fourth protruding portion PT4 may be a portion of the field plate FP, which is directly in contact with and connected to the third protruding portion PT3.

A first connection portion CP1 may be arranged between the first protruding portion PT1 and the second protruding portion PT2. The first connection portion CP1 may be arranged on a first portion 120P1 of the dielectric layer 120. The first connection portion CP1 may be in direct contact with the first portion 120P1 of the dielectric layer 120 on the first portion 120P1 of the dielectric layer 120. The first connection portion CP1 may be in direct contact with each of the first protruding portion PT1 and the second protruding portion PT2, thereby allowing the first and second protruding portions to be connected to each other.

A second connection portion CP2 may be arranged between the second protruding portion PT2 and the third protruding portion PT3. The second connection portion CP2 may be arranged on a second 120P2 of the dielectric layer 120. The second connection portion CP2 may be in direct contact with the second portion 120P2 of the dielectric layer 120 on the second portion 120P2 of the dielectric layer 120. The second connection portion CP2 may be in direct contact with each of the second protruding portion PT2 and the third protruding portion PT3, thereby allowing the second and third protruding portions to be connected to each other.

The second field plate portion FP2 may overlap, along a first direction D1, a first portion 11P of the first field plate portion FP1 and a first portion 120P1 of the dielectric layer 120. The first direction D1 may be a direction parallel to an upper surface 100U of the substrate 100a. A first portion 21P of the second field plate portion FP2 may overlap, along the first direction D1, the second portion 120P2 of the dielectric layer 120 and the third field plate portion FP3.

The third field plate portion FP3 may overlap, along the first direction D1, the second portion 120P2 of the dielectric layer 120, the first portion 21P of the second field plate portion FP2, a portion of the first portion 120P1 of the dielectric layer 120, and a second portion 12P of the first field plate portion FP1. The second portion 12P of the first field plate portion FP1 may be a part of the first portion 11P of the first field plate portion FP1.

A third portion 13P of the first field plate portion FP1 may be a remaining portion of the first field plate portion FP1 that fills the first recess r1, excluding the first portion 11P of the first field plate portion FP1. The third portion 13P of the first field plate portion FP1 may overlap the dielectric layer 120 along the first direction D1.

The first field plate portion FP1, the second field plate portion FP2, the third field plate portion FP3, the first protruding portion PT1, the second protruding portion PT2, the third protruding portion PT3, the first connection portion CP1, and the second connection portion CP2 may include the same material. The first field plate portion FP1, the second field plate portion FP2, the third field plate portion FP3, the first protruding portion PT1, the second protruding portion PT2, the third protruding portion PT3, the first connection portion CP1, and the second connection portion CP2 may include a conductive material. That is, the field plate FP may include a conductive material. For example, the field plate FP may include Ti, Ta, TiN, TaN, or a combination thereof. Alternatively, for example, the field plate FP may include Si doped with Al or Cu, or an alloy including such materials.

The gate electrode 112 may be spaced apart from the first field plate portion FP1, the second field plate portion FP2, and the third field plate portion FP3, and may be arranged within the dielectric layer 120.

The field plate FP of the semiconductor device 10 of the present disclosure not only fills the recesses r1, r2, and r3, but also includes the protruding portions PT1, PT2, PT3, and PT4 and the connection portions CP1 and CP2, thereby dispersing an electric field applied to the semiconductor device 10, preventing breakdown of the field plate FP, and improving the reliability of the device.

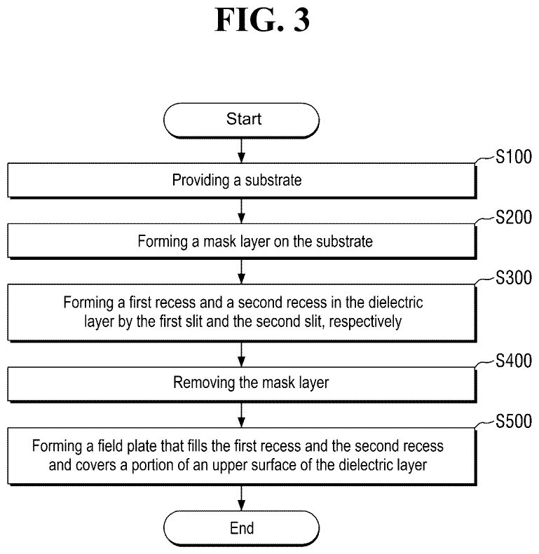

Hereinafter, a method for manufacturing a semiconductor device comprising a gallium nitride layer according to an embodiment of the present disclosure will be described with reference to FIGS. 3 to 6. For clarity of description, overlapping contents previously described are briefly mentioned or omitted.

FIG. 3 is a flowchart for explaining a method for manufacturing a semiconductor device according to an embodiment of the present disclosure.

Referring to FIG. 3, the method for manufacturing a semiconductor device according to an embodiment of the present disclosure may include a step S100 of providing a substrate.

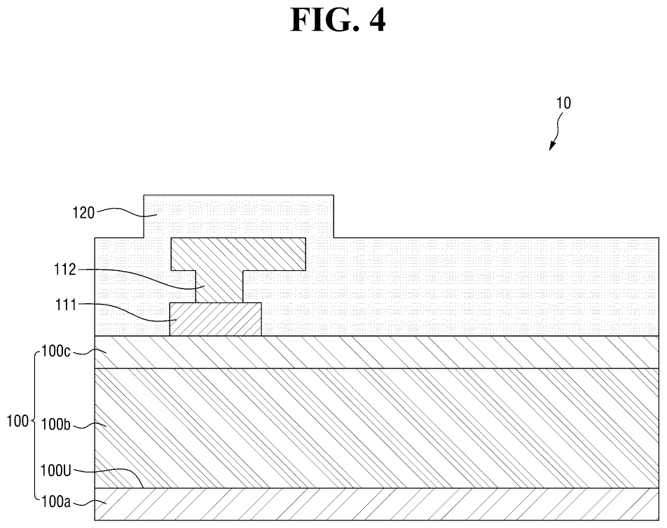

FIG. 4 is a cross-sectional view for explaining step S100 of FIG. 3.

Referring to FIGS. 3 and 4, when the substrate 100a is provided, a dielectric layer 120 may be formed on the substrate 100a. In addition, when the substrate 100a is provided, a gate electrode 112 may be formed in the dielectric layer 120. Furthermore, when the substrate 100a is provided, a semiconductor layer 100b and a semiconductor compound layer 100c may also be formed on the substrate 100a.

A doped semiconductor layer 111 may be formed between the gate electrode 112 and the substrate 100a. The doped semiconductor layer 111 may be formed in the dielectric layer 120.

Referring to FIG. 3, the method for manufacturing a semiconductor device according to an embodiment of the present disclosure may include a step S200 of forming a mask layer on the substrate.

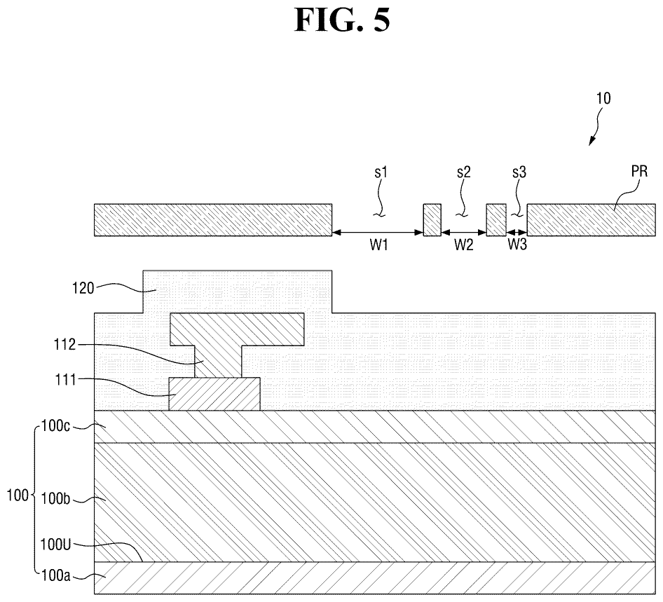

FIG. 5 is a cross-sectional view for explaining step S200 of FIG. 3.

Referring to FIGS. 3 and 5, a mask layer PR including a first slit s1, a second slit s2, and a third slit s3 may be formed on the substrate 100a.

A first width W1 of the first slit s1, a second width W2 of the second slit s2, and a third width W3 of the third slit s3 may be different from one another. In the first slit s1, which is the slit closest to the gate electrode 112, the slit width may gradually decrease as the distance from the gate electrode 112 increases.

Each of the first slit s1, the second slit s2, and the third slit s3 may expose a portion of the dielectric layer 120.

Although the mask layer PR is illustrated in the drawings as including three slits, it is not limited thereto. If the slit width gradually decreases with increasing distance from the slit closest to the gate electrode 112, a variety of numbers of slits may be included as needed.

Referring again to FIG. 3, the method for manufacturing a semiconductor device according to an embodiment of the present disclosure may include a step S300 of forming a first recess and a second recess in the dielectric layer by the first slit and the second slit, respectively.

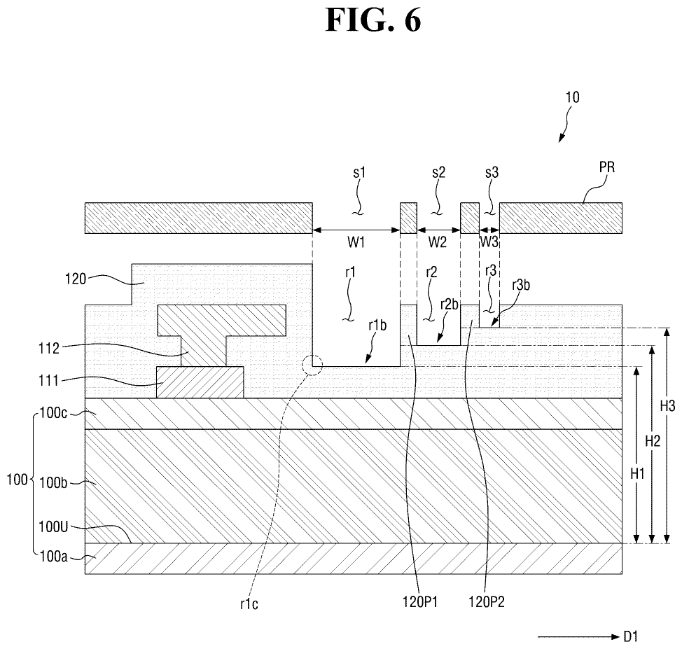

FIG. 6 is a cross-sectional view for describing step S300 of FIG. 3.

Referring to FIGS. 3 and 6, portions of the dielectric layer 120 exposed by the respective first slit s1, second slit s2, and third slit s3 of the mask layer PR may be removed, and a first recess r1, a second recess r2, and a third recess r3 may be formed in the dielectric layer 120.

For example, a portion of the dielectric layer 120 exposed by the first slit s1 may be removed, so that a first recess r1 having a first bottom surface r1b with a first width W1 may be formed in the dielectric layer 120. For example, a portion of the dielectric layer 120 exposed by the second slit s2 may be removed, so that a second recess r2 having a second bottom surface r2b with a second width W2 may be formed in the dielectric layer 120. For example, a portion of the dielectric layer 120 exposed by the third slit s3 may be removed, so that a third recess r3 having a third bottom surface r3b with a third width W3 may be formed in the dielectric layer 120.

Since the widths of the respective slits of the mask layer PR are different, in a process of removing a portion of the dielectric layer 120 (e.g., an etching process), depending on the aspect ratio, the portion of the dielectric layer 120 exposed by a slit having a large width may be removed more widely and deeply, and the portion of the dielectric layer 120 exposed by a slit having a narrow width may be removed more narrowly and shallowly. According to the aspect ratio, a wide and deep recess (e.g., the first recess r1) may be formed in the portion of the dielectric layer 120 exposed by the slit having a large width, and a narrow and shallow recess (e.g., the second recess r2 or the third recess r3) may be formed in the portion of the dielectric layer 120 exposed by the slit having a narrow width. With reference to the upper surface 100U of the substrate 100a, a first height H1 to the first bottom surface r1b may be formed to be lower than a second height H2 to the second bottom surface r2b. In addition, with reference to the upper surface 100U of the substrate 100a, the second height H2 to the second bottom surface r2b may be formed to be lower than a third height H3 to the third bottom surface r3b.

Referring again to FIG. 3, the method for manufacturing a semiconductor device according to an embodiment of the present disclosure may include a step S400 of removing the mask layer. A cross-sectional view after the mask layer is removed may be the same as FIG. 2.

The method for manufacturing a semiconductor device according to an embodiment of the present disclosure may include a step S500 of forming a field plate that fills the first recess and the second recess and covers a portion of an upper surface of the dielectric layer. A cross-sectional view in which the field plate is formed may be the same as FIG. 1A.

The recesses may be formed not only in the shape shown in FIG. 1A, but also in the shapes shown in each of FIGS. 1B, 1C, and 1D.

The method for manufacturing a semiconductor device comprising a gallium nitride layer according to the present disclosure may form the field plate through a single process using one mask layer, thereby securing economic efficiency.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

1. A semiconductor device comprising:
a substrate;
a semiconductor material layer on the substrate;
a dielectric layer on the semiconductor material layer; and
a first recess, a second recess, and a third recess arranged in the dielectric layer and spaced apart from one another;
a first field plate portion filling the first recess;
a second field plate portion filling the second recess; and
a third field plate portion filling the third recess,
wherein a first width of a first bottom surface of the first recess, a second width of a second bottom surface of the second recess, and a third width of a third bottom surface of the third recess are different from one another.

2. The semiconductor device according to claim 1, wherein the second recess is arranged between the first recess and the third recess, and
the second field plate portion is arranged between the first field plate portion and the third field plate portion.

3. The semiconductor device according to claim 2, wherein the first width is greater than the second width, and
the second width is greater than the third width.

4. The semiconductor device according to claim 1, wherein the dielectric layer includes:
a first portion between the first recess and the second recess, and
a second portion between the second recess and the third recess.

5. The semiconductor device according to claim 4, wherein the second field plate portion overlaps, along a first direction parallel to an upper surface of the substrate, a first portion of the first plate portion and the first portion of the dielectric layer, and
the third field plate portion overlaps, along the first direction, a second portion of the first plate portion, a portion of the first portion of the dielectric layer, a first portion of the second field plate portion, and the second portion of the dielectric layer.

6. The semiconductor device according to claim 4, further comprising:
a first protruding portion on the first field plate portion;
a second protruding portion on the second field plate portion;
a third protruding portion on the third field plate portion;
a first connection portion that connects the first protruding portion and the second protruding portion, and is arranged on the first portion of the dielectric layer;
a second connection portion that connects the second protruding portion and the third protruding portion, and is arranged on the second portion of the dielectric layer; and
a fourth protruding portion that is connected to the third protruding portion and is arranged on an upper surface of the dielectric layer.

7. The semiconductor device according to claim 6, wherein the first field plate portion, the second field plate portion, the third field plate portion, the first protruding portion, the second protruding portion, the third protruding portion, the first connection portion, and the second connection portion include the same material.

8. The semiconductor device according to claim 1, wherein a first height from an upper surface of the substrate to the first bottom surface, a second height to the second bottom surface, and a third height to the third bottom surface are different from one another.

9. The semiconductor device according to claim 8, wherein the third height is greater than the second height, and
the second height is greater than the first height.

10. The semiconductor device according to claim 1, further comprising:
a gate electrode that is spaced apart from the first field plate portion, the second field plate portion, and the third field plate portion, is arranged in the dielectric layer, and is arranged on the substrate.

11. A semiconductor device comprising:
a substrate;
a semiconductor material layer on the substrate;
a dielectric layer on the semiconductor material layer;
a first field plate portion and a second field plate portion arranged in the dielectric layer and spaced apart from each other;
a first portion of the dielectric layer arranged between the first field plate portion and the second field plate portion;
a first protruding portion on the first field plate portion;
a second protruding portion on the second field plate portion; and
a first connection portion arranged on the first portion of the dielectric layer and connecting the first protruding portion and the second protruding portion.

12. The semiconductor device according to claim 11, further comprising:
a first recess and a second recess arranged in the dielectric layer and spaced apart from each other,
wherein the first field plate portion fills the first recess, and
the second field plate portion fills the second recess.

13. The semiconductor device according to claim 12, wherein a first width of a first bottom surface of the first recess and a second width of a second bottom surface of the second recess are different from each other.

14. The semiconductor device according to claim 13, wherein the first width is greater than the second width.

15. The semiconductor device according to claim 13, wherein a first height from an upper surface of the substrate to the first bottom surface and a second height to the second bottom surface are different from each other.

16. The semiconductor device according to claim 15, wherein the second height is greater than the first height.

17. The semiconductor device according to claim 11, wherein the second field plate portion overlaps, along a first direction parallel to an upper surface of the substrate, a first portion of the first plate portion and the first portion of the dielectric layer.

18. The semiconductor device according to claim 11, wherein the first field plate portion, the second field plate portion, the first protruding portion, the second protruding portion, and the first connection portion include the same material.

19. The semiconductor device according to claim 11, further comprising:
a gate electrode that is spaced apart from the first field plate portion and the second field plate portion, is arranged in the dielectric layer, and is arranged on the substrate.

20. A method for manufacturing a semiconductor device, comprising:
providing a substrate on which a dielectric layer is formed and in which a gate electrode is formed in the dielectric layer;
forming a mask layer on the substrate, the mask layer including a first slit having a first width and a second slit having a second width, wherein the first width and the second width are different from each other;
removing a portion of each of the portions of the dielectric layer exposed by the first slit and the second slit, respectively, to form a first recess by the first slit and a second recess by the second slit in the dielectric layer;
removing the mask layer; and
forming a field plate that fills the first recess and the second recess and covers a portion of an upper surface of the dielectric layer.

21. The method for manufacturing a semiconductor device according to claim 20, wherein a first height from an upper surface of the substrate to a first bottom surface of the first recess is different from a second height to a second bottom surface of the second recess.

22. The method for manufacturing a semiconductor device according to claim 20, wherein the field plate is formed such that a first field plate portion that fills the first recess and a second field plate portion that fills the second recess are connected to each other.
